(19) United States
(12) Patent Application Publication
(10) Pub. No.: US 2012/0187401 A1
(43) Pub. Date: Jul. 26, 2012

(54) DEVICE ALLOWING SUPPRESSION OF STRESS ON CHIP

(75) Inventors: Toshihiro WAKI, Tokyo (JP); Toru ISHIKAWA, Tokyo (JP)

(73) Assignee: Elpida Memory, Inc.

(21) Appl. No.: 13/353,874

(22) Filed: Jan. 19, 2012

(30) Foreign Application Priority Data
Jan. 25, 2011 (JP) 2011-012926

(51) Int. Cl. H01L 23/538

(52) U.S. Cl. 257/48; 257/774; 257/E23.174

(57) ABSTRACT

A device includes: a first substrate including a plurality of first electrodes; a plurality of chips each including a plurality of through electrodes, the chips being stacked with each other such that the through electrodes of a lower one of the chips are connected respectively the through electrodes of an upper one of the chips to provide a chip stacked body; and a second substrate cooperating the first substrate to sandwich the chip stacked body between the first and second substrates, the second substrate including a plurality of second electrodes on a first surface that is opposite to a second surface facing the chip stacked body, each of the second electrodes being electrically connected to an associated one of the through electrodes of an uppermost one of the chips of the chip stacked body.

This application is based upon and claims the benefit of priority from Japanese Patent Application No. 2011-12926 filed on Jan. 25, 2011, the content of which is incorporated by reference.

### BACKGROUND OF THE INVENTION

1. Field of the Invention

The present invention relates to a device and a semiconductor device which have a plurality of chips.

2. Description of Related Art

JP2007-36184A discloses an exemplary semiconductor device in which a plurality of chips having electrodes that penetrate through a chip (hereinafter called ‘through electrodes’) are stacked. FIG. 1 of JP2007-36184A discloses a structure in which a plurality of stacked chips are connected to each other via through electrodes.

In the semiconductor device disclosed in JP2007-36184A, a plurality of chips are stacked on a wiring board and the chips are electrically connected to each other via through electrodes formed on each chip. In the configuration disclosed in JP2007-36184A, through electrodes are exposed on the front surface of the chip disposed on the uppermost level. When stress occurs due to expansion or contraction of through electrodes caused by a temperature change or the like in fabrication processes, the maximum stress is put on the portion of the through electrodes of the chip disposed on the uppermost level, and cracks may occur in the chip disposed on the uppermost level.

### SUMMARY

In one embodiment, there is provided a device that includes: a first substrate including a plurality of first electrodes; a plurality of chips each including a plurality of through electrodes, the chips being stacked with each other such that the through electrodes of a lower one of the chips are connected respectively the through electrodes of an upper one of the chips to provide a chip stacked body; and a second substrate cooperating the first substrate to sandwich the chip stacked body between the first and second substrates, the second substrate including a plurality of second electrodes on a first surface that is opposite to a second surface facing the chip stacked body, each of the second electrodes being electrically connected to an associated one of the through electrodes of an uppermost one of the chips of the chip stacked body.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross sectional view illustrating an exemplary configuration of a semiconductor device according to a first embodiment;

FIG. 2 is a cross sectional view illustrating an exemplary configuration of a through electrode shown in FIG. 1;

FIG. 3 is a plan view illustrating an exemplary layout of through electrodes of a semiconductor chip shown in FIG. 1;

FIG. 4 is a plan view illustrating another exemplary layout of through electrodes of the semiconductor chip shown in FIG. 1;

FIG. 5 is a plan view illustrating an exemplary layout of electrodes on the front surface of substrate 5 shown in FIG. 1;

FIG. 6 is a cross sectional view on line A-A′ shown in FIG. 5;

FIG. 7 is a plan view illustrating an exemplary layout of electrodes on the back surface of substrate 5 shown in FIG. 1;

FIG. 8 is a plan view illustrating another exemplary layout of electrodes on the back surface of substrate 5;

FIG. 9 is a diagram illustrative of a method of testing a semiconductor chip in the semiconductor device shown in FIG. 1;

FIGS. 10A to 10D are cross sectional views illustrating a procedure of a method for fabricating the semiconductor device according to this embodiment;

FIG. 11 is a cross sectional view illustrative of a method for testing a semiconductor chip in a state of a chip stacked body; and

FIG. 12 is a cross sectional view illustrating an exemplary configuration of a semiconductor device according to a second embodiment.

### DETAILED DESCRIPTION OF THE PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

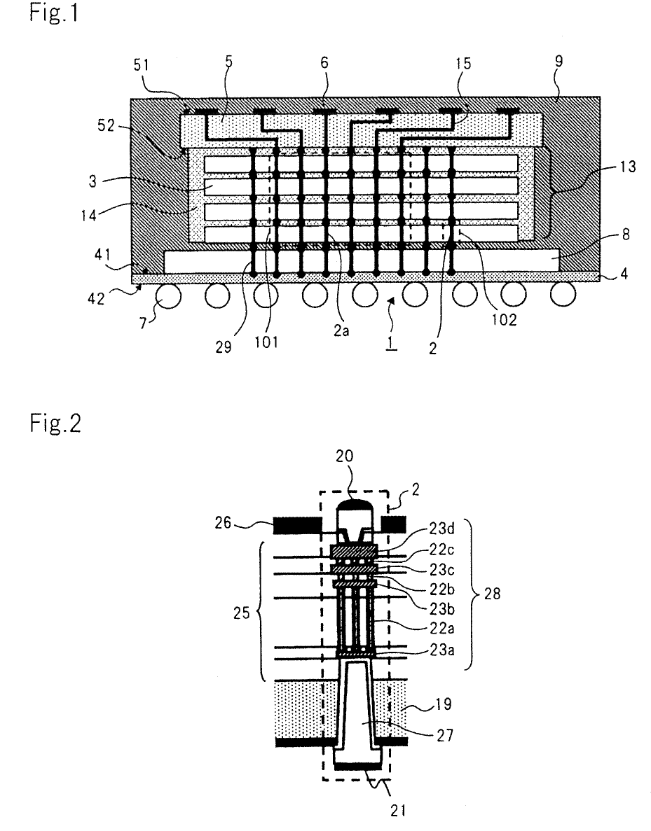

The configuration of a semiconductor device according to this embodiment will be described. FIG. 1 is a cross sectional view illustrating an exemplary configuration of a semiconductor device according to this embodiment.

As shown in FIG. 1, semiconductor device 1 has package substrate 4, chip stacked body 13 having a plurality of semiconductor chips 3 stacked, and substrate 5. Each of the plurality of semiconductor chips 3 has a plurality of through electrodes 2. Package substrate 4 as a wiring board has two surfaces, front surface 41 and back surface 42, in which chip stacked body 13 is provided on the front surface 41 side, and a plurality of electrodes 7 are provided on back surface 42.

The plurality of electrodes 7 are arranged at a pitch larger than the pitch between through electrodes 2. Each of the plurality of electrodes 7 is electrically connected to each of the plurality of through electrodes 2. Electrode 7 is a solder ball, for example. Electrode 7 corresponds to a first electrode, and package substrate 4 corresponds to a first substrate.

Substrate 5 is provided on the opposite side of package substrate 4 based on chip stacked body 13. Substrate 5 is disposed on chip stacked body 13. A plurality of electrodes 6 are provided on front surface 51 of substrate 5. The plurality of electrodes 6 are arranged at a pitch larger than the pitch between through electrodes 2. The plurality of electrodes 6 are electrically connected to a part of through electrodes among the plurality of through electrodes 2. In this embodiment, the through electrode connected to electrode 6 is expressed with reference numeral “2a” among the plurality of through electrodes 2. In the exemplary configuration shown in FIG. 1, through electrodes 2a are provided in broken line frame 101. The pitch between through electrodes 2 corresponds to a first pitch, the pitch between electrodes 6 corresponds to a second pitch, and the pitch between electrodes 7 corresponds to a third pitch.

Semiconductor chip 3 is a semiconductor memory chip such as a DRAM (Dynamic Random Access Memory), SRAM (Static Random Access Memory), PRAM (Phase change Random Access Memory), and a flash memory, for example. However, semiconductor chip 3 may be an IC chip other than memories.

As shown in FIG. 1, a different type of chip from semiconductor chip 3 may be provided between chip stacked body 13 and package substrate 4. In semiconductor device 1 shown in FIG. 1, ASIC (Application Specific Integrated Circuit) chip 8 that functions as a controller for semiconductor chip 3 is provided between chip stacked body 13 and package substrate 4. ASIC chip 8 has a plurality of through electrodes 29. Through electrodes 29 correspond to through electrodes 2 of semiconductor chip 3 that face to ASIC chip 8, and each of the plurality of through electrodes 29 is connected to each of the plurality of through electrodes 2.

In chip stacked body 13 according to this embodiment, resin 14 is provided to cover the side surfaces of semiconductor chips 3 and bury the gap between semiconductor chips 3. Encapsulation resin 9 is provided on package substrate 4 to cover a stacked structure formed of ASIC chip 8, chip stacked body 13, and substrate 5, and bury the gap between chip stacked body 13 and ASIC chip 8. Encapsulation resin 9 covers front surface 51 and side surfaces of substrate 5 including electrodes 6, and covers the side surfaces of chip stacked body 13 and package substrate 4. Resin 14 and encapsulation resin 9 are one kind of insulating film.

It is noted that in the exemplary configuration shown in FIG. 1, although the structure of stacking four semiconductor chips 3 is illustrated as chip stacked body 13, the number of semiconductor chips 3 is not limited to four.

Through electrode 2 shown in FIG. 1 will be described in detail. FIG. 2 is a cross sectional view illustrating an exemplary configuration of the through electrode shown in FIG. 1. FIG. 2 is a diagram enlarging the portion indicated by broken line frame 102 shown in FIG. 1.

Through electrode 2 has substrate penetrating electrode 27 that penetrates semiconductor substrate 19, interconnection structure 28 connected to substrate penetrating electrode 27, front surface electrode 20, and back surface electrode 21. Front surface electrode 20 is connected to back surface electrode 21 via interconnection structure 28 and substrate penetrating electrode 27. Interconnection structure 28 is constituted of pluralities of contact plugs 22a to 22c and pluralities of wiring pads 23a to 23d. These contact plugs 22a to 22c and wiring pads 23a to 23d are provided in insulating film 25. Passivation film 26 is provided on insulating film 25, and front surface electrode 20 is disposed in an opening in passivation film 26.

Semiconductor chips 3 that face to each other are connected to each other via through electrodes 2, and lowermost semiconductor chip 3 and ASIC chip 8 are connected to each other via through electrodes 2. It is noted that the numbers of layers of the contact plugs and the wiring pads in interconnection structure 28 are examples and are not limited to the numbers shown in FIG. 2.

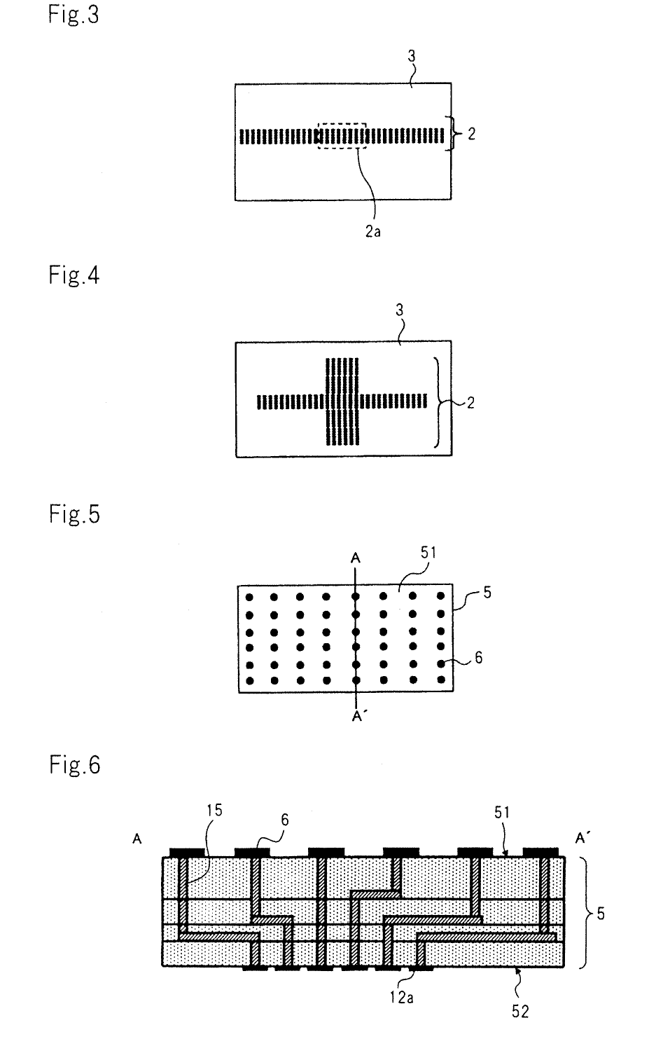

Next, the layout of through electrodes 2 in the plane of semiconductor chip 3 will be described. FIG. 3 is a plan view illustrating an exemplary layout of the through electrodes of the semiconductor chip shown in FIG. 1.

As shown in FIG. 3, through electrodes 2 are arranged at a very narrow pitch. Through electrodes 2 are arranged at a pitch of about 40 μm, for example. In the exemplary configuration shown in FIG. 3, six rows of through electrodes 2 are arranged at a predetermined pitch along the longitudinal direction of semiconductor chip 3 in such a way that the rows pass through near the center of semiconductor chip 3. In six rows of through electrodes 2, through electrodes 2a provided at the center part of semiconductor chip 3 (a region surrounded by a broken line frame shown in FIG. 3) are electrically connected to electrodes 6 shown in FIG. 1.

It is noted that FIG. 3 shows an example in which through electrodes 2a are collectively provided at the center part of semiconductor chip 3. However, the layout of through electrodes 2a is not limited thereto. Through electrodes 2a may be arranged in such a way that through electrodes 2a are scattered along the longitudinal direction of semiconductor chip 3. It is acceptable for through electrodes 2a to be arranged so that they correspond to the configuration of circuits, wirings, and so on in semiconductor chip 3.

The arrangement of through electrodes 2 of semiconductor chip 3 is not limited to the layout shown in FIG. 3. FIG. 4 is a plan view illustrating another exemplary layout of the through electrodes. As shown in FIG. 4, through electrodes 2 may be arranged in such a way that the rows of through electrode 2 cross each other in the shape of a cross. In the configuration shown in FIG. 4, six rows of through electrodes 2 are arranged along the longitudinal direction of semiconductor chip 3 and six rows of through electrodes 2 are arranged along a direction vertical to the longitudinal direction of semiconductor chip 3. Six rows in the longitudinal direction and six rows in the direction vertical to the longitudinal direction overlap with each other near the center of semiconductor chip 3.

Next, the configuration of substrate 5 shown in FIG. 1 will be described in detail. Substrate 5 corresponds to a second substrate. FIG. 5 is a plan view illustrating an exemplary layout of the electrodes on the front surface of the substrate shown in FIG. 1. Here, in order to make a comparison with the layout of through electrodes 2 of semiconductor chip 3 shown in FIG. 3, the size of substrate 5 shown in FIG. 5 is matched with the size of semiconductor chip 3 shown in FIG. 3.

As shown in FIG. 5, electrodes 6 are arranged at a pitch larger than the pitch between through electrodes 2 shown in FIG. 3. Electrodes 6 are arranged at a pitch of about 0.5 mm, for example. Electrode 6 is configured in which the area of the two-dimensional pattern is larger than the area of the two-dimensional pattern of front surface electrode 20 of through electrode 2 shown in FIG. 2. Thus, measurement probe needles are facilitated to contact with electrodes 6 in testing semiconductor chip 3. The term “test” mentioned here means an inspection to determine whether semiconductor chip 3 normally operates. In the following, a “test signal” referrers to a signal that is used in testing semiconductor chip 3 and that is inputted to semiconductor chip 3. A method of testing semiconductor chip 3 will be described later with reference to the drawings.

In this embodiment, the case is explained where electrodes 6 are arranged in an array as shown in FIG. 5. However, the arrangement of electrodes 6 is not limited to the layout shown in FIG. 5. The pitch between electrodes 6 and the arrangement of electrodes 6 may be determined so as to match with the probe needles of an inspection apparatus for use in testing semiconductor chip 3.

FIG. 6 is a cross sectional view on line A-A′ shown in FIG. 5. As shown in FIG. 6, substrate 5 has electrode 6 provided on front surface 51, electrode 12a provided on back surface 52, and interconnection 15 connecting electrode 6 to electrode 12a. Electrode 12a is connected to through electrode 2a shown in FIG. 3. With this configuration, electrode 6 is electrically connected to through electrode 2a corresponding to this electrode 6 via electrode 12a and interconnection 15. Electrode 6 corresponds to a second electrode, and electrode 12a corresponds to a third electrode.

Substrate 5 has a multi-layer interconnection structure in which a plurality of wiring layers are stacked via an insulating film as a wiring board. In the configuration shown in FIG. 6, the case is shown where four wiring layers are provided including a layer in which electrodes 6 are formed. However, the number of wiring layers is not limited to the case of four layers. Necessary wiring layers can be changed appropriately according to the number and layout of electrodes 6. For example, the multi-layer interconnection structure may be a two-layer structure which has a wiring layer formed on front surface 51 of substrate 5 and a wiring layer formed on back surface 52 of substrate 5.

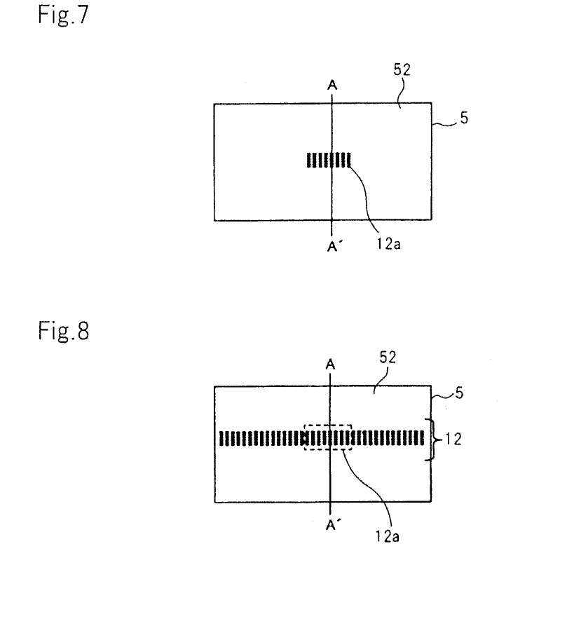

FIG. 7 is a plan view illustrating an exemplary layout of the electrodes on the back surface of the substrate shown in FIG. 1.

As shown in FIG. 7, electrodes 12a are provided on back surface 52 of substrate 5 at a pitch and in an arrangement in a similar to the pith and arrangement of through electrodes 2a, corresponding to through electrodes 2a shown in FIG. 3. In the exemplary configuration shown in FIG. 7, only electrodes 12a connected to electrodes 6 via interconnection 15 are provided on back surface 52 of substrate 5. However, electrodes that are not connected to electrodes 6 may be provided.

FIG. 8 is a plan view illustrating another exemplary layout of the electrodes on the back surface of substrate 5. As shown in FIG. 8, electrodes 12 may be provided such that they correspond to all of through electrodes 2 shown in FIG. 3. Electrodes 12 are provided at a pitch and in an arrangement that is similar to through electrodes 2. However, interconnection 15 is not connected to electrodes other than electrodes 12a from among electrodes 12. Thus, only electrode 12a contacted with through electrode 2a is electrically connected to electrode 6.

For the material of substrate 5, any substrates are fine as long as substrates have electrodes electrically connectable to through electrodes 2a of semiconductor chip 3. For example, in the case where semiconductor chip 3 is a semiconductor device having a silicon substrate, a silicon substrate may be used for a base of substrate 5, whose thermal expansion coefficient is close to that of semiconductor chip 3.

With the aforementioned configuration, each of the plurality of electrodes 6 is electrically connected to each of the plurality of through electrodes 2a via interconnection 15 and electrode 12a. Thus, it is possible to input/output signals between semiconductor chip 3 and the outside via electrodes 6. For example, through electrode 2a electrically that is connected to electrode 6 is used for a through-hole interconnection to 2 0 transmit test signals for semiconductor chip 3, so that it is possible to test semiconductor chip 3 via electrodes 6 in a state prior to mounting chip stacked body 13 on package substrate 4. A method of testing semiconductor chip 3 prior to mounting chip stacked body 13 on package substrate 4 will be described later in detail.

Next, a configuration related to testing semiconductor chip 3 will be described in semiconductor device 1 after mounting chip stacked body 13 on package substrate 4, before describing a method of testing semiconductor chip 3 prior to mounting chip stacked body 13 on package substrate 4.

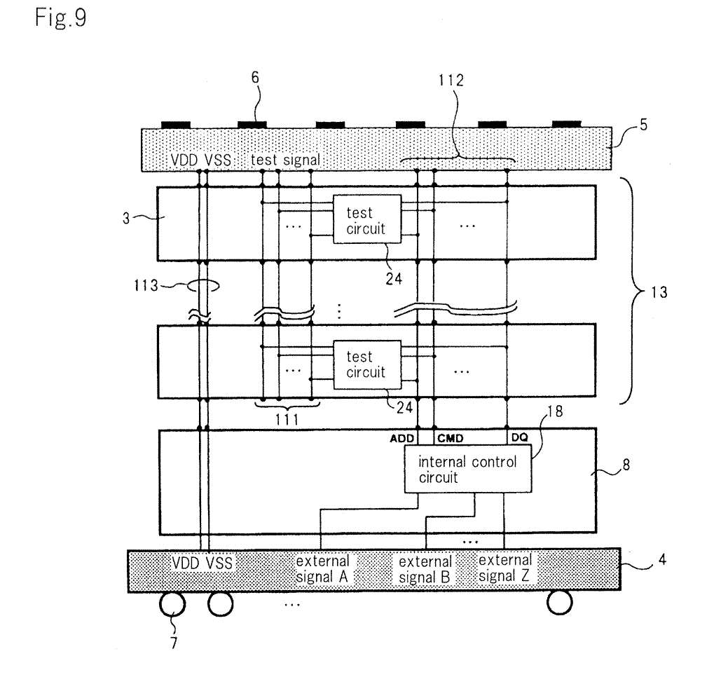

FIG. 9 is a schematic cross sectional view illustrative of a method of testing a semiconductor chip in the semiconductor device shown in FIG. 1. A configuration related to the present invention will be described in detail. A configuration related to the general operation of semiconductor device 1 is omitted in the drawing, and the detailed description thereof is omitted.

As shown in FIG. 9, each of the plurality of semiconductor chips 3 is provided with test circuit 24 to be an internal circuit for testing the operation of semiconductor chip 3. ASIC chip 8 is provided with internal control circuit 18 for controlling the plurality of semiconductor chips 3. Internal control circuit 18 controls data input/output of individual semiconductor chips 3 in the general operation of semiconductor device 1, and controls test circuit 24 of individual semiconductor chips 3 in testing.

Through electrodes 2a explained with reference to FIGS. 1 to 4 are categorized into through electrodes that are connected to substrate 5 via adjacent semiconductor chip 3 and through electrodes that are connected to both substrate 5 and package substrate 4 via adjacent semiconductor chip 3 and ASIC chip 8. A group of through electrodes that are connected to substrate 5 is through electrode group 111, and a group of through electrodes that are connected to both substrate 5 and package substrate 4 is through electrode group 113. Among through electrodes 2, a through electrode group, except through electrodes 2a, is through electrode group 112. Although through electrode group 112 is connected to package substrate 4 via adjacent semiconductor chip 3 and ASIC chip 8, through electrode group 112 is not necessarily connected to substrate 5.

The through electrodes belonging to through electrode group 111 are connected to substrate 5 via adjacent semiconductor chip 3, and connected to electrodes 6 via interconnections 15 shown in FIG. 6, but interconnections 15 are not shown in FIG. 9. The through electrodes belonging to through electrode group 111 are connected to test circuit 24 of each semiconductor chip 3. Through electrode group 111 functions as transmission lines for the test signal of semiconductor chip 3, but through electrode group 111 is not used after chip stacked body 13 is mounted on package substrate 4.

The through electrodes belonging to through electrode group 112 are connected to ASIC chip 8 via adjacent semiconductor chip 3, and connected to electrodes 7 of package substrate 4 via internal control circuit 18 of ASIC chip 8. Through electrode group 112 functions as transmission lines for transmitting signals between semiconductor chip 3 and ASIC chip 8 with respect to semiconductor chips 3 of semiconductor device 1 after chip stacked body 13 is mounted on package substrate 4, even in both cases of general operations and testing. In the case where semiconductor chip 3 is a DRAM, for example, the types of signals to be transmitted are address signal ADD, command signal CMD, data DQ, and so on.

The through electrodes belonging to through electrode group 113 are connected to substrate 5 via adjacent semiconductor chip 3, and connected to electrodes 6 via interconnections 15 shown in FIG. 6, but interconnections 15 are not shown in FIG. 9. The through electrodes belonging to through electrode group 113 are connected to ASIC chip 8 via adjacent semiconductor chip 3, and connected to electrodes 7 of package substrate 4 via through electrodes 29 shown in FIG. 1, but through electrodes 29 are not shown in FIG. 9.

The through electrodes belonging to through electrode group 113 are used for interconnections to supply power supply voltage VDD and ground potential VSS to each semiconductor chip 3 and ASIC chip 8. Here, a case will be described where through electrode group 113 is used for interconnections to supply power supply voltage VDD and ground potential VSS to the chips. However, through electrode group 113 may be used for transmission lines to transmit signals which will be used in semiconductor chips 3 and ASIC chip 8, to the chips. Although through electrode group 113 is the same with through electrode group 112 in that through electrode group is connected to package substrate 4 via ASIC chip 8, but through electrode group 113 is different from through electrode group 112 in that through electrode group 113 is connected to electrodes 7 of package substrate 4 not via an internal circuit such as internal control circuit 18.

Here, in semiconductor device 1 described above, operation in general and operation in testing will be briefly described. First, the general operations of semiconductor chips 3 of semiconductor device 1 will be described.

Power supply voltage VDD and ground potential VSS are externally supplied to the chips via electrodes 7 of package substrate 4 and through electrode group 113, and a plurality of external signals A to Z are inputted to ASIC chip 8 via electrodes 7. External signals A to Z also include a chip select signal that specifies any one of the plurality of semiconductor chips 3. After processing external signals A to Z at internal control circuit 18, signals such as address signal ADD and command signal CMD are transmitted from ASIC chip 8 to semiconductor chip 3 via through electrode group 112. In the case of writing data, these signals include data DQ. Semiconductor chip 3 specified by the chip select signal reads data DQ or writes data DQ to a memory device identified by address signal ADD according to command signal CMD.

Next, a method of testing semiconductor chip 3 of semiconductor device 1 will be described. Two ways are possible as a method of testing semiconductor chip 3: (1) “the case where power and signals are externally supplied to electrodes 6 of substrate 5”; and (2) “the case where power and signals are externally supplied to electrodes 7 of package substrate 4”. Here, case (2) will be explained, and case (1) will be described later.

Power supply voltage VDD and ground potential VSS are externally supplied to the individual chips via electrodes 7 of package substrate 4 and through electrode group 113, and the plurality of external signals A to Z are inputted to ASIC chip 8 via electrodes 7. After processing external signals A to Z at internal control circuit 18, signals such as address signal ADD and command signal CMD are transmitted from ASIC chip 8 to semiconductor chip 3 via through electrode group 112. Here, the signals such as address signal ADD and command signal CMD correspond to test signals. Semiconductor chip 3 specified by the chip select signal receives the test signals inputted from ASIC chip 8 to test circuit 24, and outputs the results to electrodes 7 of package substrate 4 via through electrode group 112 and ASIC chip 8.

Thus, power is supplied to semiconductor chip 3 via electrodes 7 of package substrate 4 and through electrode group 113, and the test signals are transmitted to semiconductor chip 3 via electrodes 7 and through electrode group 112, so that it is possible to output the results of the test for semiconductor chip 3 via through electrode group 112 and electrode 7.

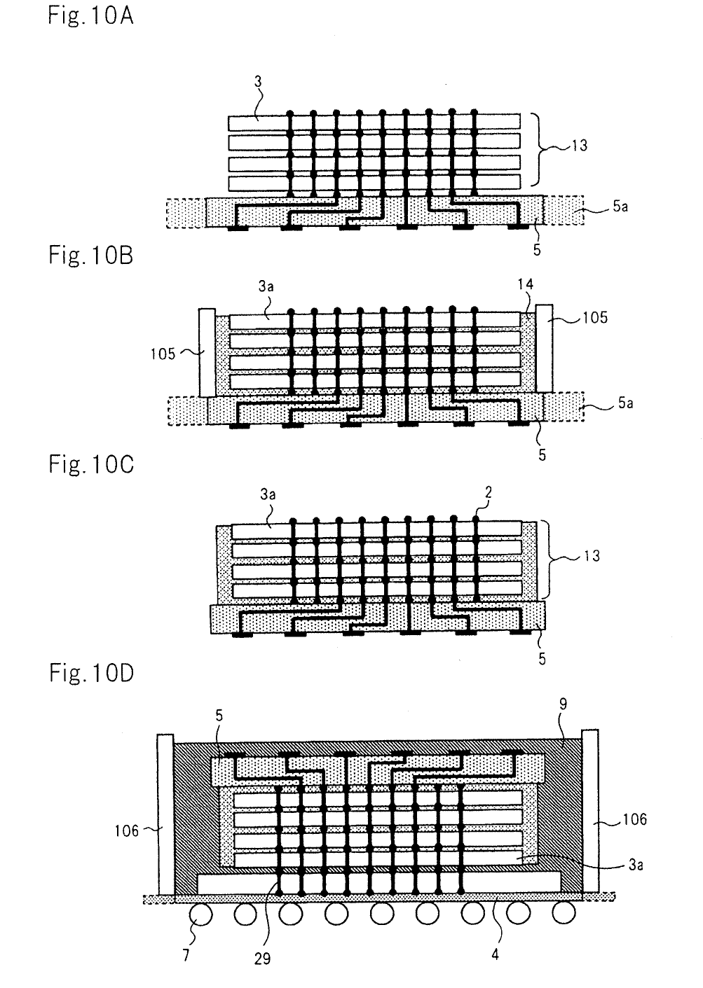

Next, a method of fabricating the semiconductor device according to this embodiment will be described. FIGS. 10A to 10D are cross sectional views illustrating a procedure of a method of fabricating the semiconductor device according to this embodiment. Here, detailed descriptions of methods of fabricating semiconductor chip 3, package substrate 4, ASIC chip 8, and substrate 5 are omitted. The assumption is that package substrate 4 that is mounted with ASIC chip 8 is prepared beforehand.

As shown in FIG. 10A, four semiconductor chips 3 are stacked on substrate 5a to prepare chip stacked body 13. In this stacking, four semiconductor chips 3 are stacked and the corresponding electrodes are connected to each other in such a way that the positions of through electrodes 2 are matched between semiconductor chips 3 that face each other. Through electrodes 2a of lowermost semiconductor chip 3 are connected to electrodes 12a of substrate 5a. Substrate 5a corresponds to a substrate in which a plurality of substrates 5 are provided in a flat shape. Even if stress occurs in the expansion or contraction of through electrodes 2 due to a temperature change or the like, the stress is absorbed in substrate 5a.

As shown in FIG. 10B, after disposing mold 105 on substrate 5a, resin 14 is poured into the inside of mold 105 in such a way that the gap between semiconductor chips 3 of chip stacked body 13 is buried and the side surfaces of semiconductor chip 3 are covered. In doing so, as shown in FIG. 10B, resin 14 is poured into the inside of mold 105 to prevent the top face of resin 14 from exceeding the top face of topmost semiconductor chip 3a. Thus, resin 14 is filled in the gap between semiconductor chips 3 and the gap between semiconductor chip 3 and substrate 5a with the top face of topmost semiconductor chip 3a exposed.

Subsequently, after removing mold 105, substrate 5a is scribed and separated into individual substrates 5, and a structure shown in FIG. 10C is obtained. The structure shown in FIG. 10C is used to perform a test described later. A structure determined as a conforming unit from the results of the test is put up side down, and mounted on ASIC chip 8 of package substrate 4. Here, a plurality of package substrates 4 are provided in a single substrate. In mounting the structure shown in FIG. 10C on ASIC chip 8, chip stacked body 13 is disposed on ASIC chip 8 in such a way that the positions of through electrodes 2 of semiconductor chip 3a and the positions of through electrodes 29 of ASIC chip 8 are matched with each other, and the corresponding electrodes are connected to each other.

After that, as shown in FIG. 10D, mold 106 is disposed on package substrate 4, and encapsulation resin 9 is poured into the inside of mold 106 in such a way that the top face of the structure shown in FIG. 10C is covered. In doing so, even if through electrodes 2 expand or contract due to a temperature change or the like of encapsulation resin 9, stress caused by expansion or contraction is applied to substrate 5 disposed on the uppermost level, so that it is possible to prevent semiconductor chip 3 from cracking. After that, mold 106 is removed and then the plurality of package substrates 4 in a single substrate are separated into each package substrate 4, so that semiconductor device 1 shown in FIG. 1 is fabricated.

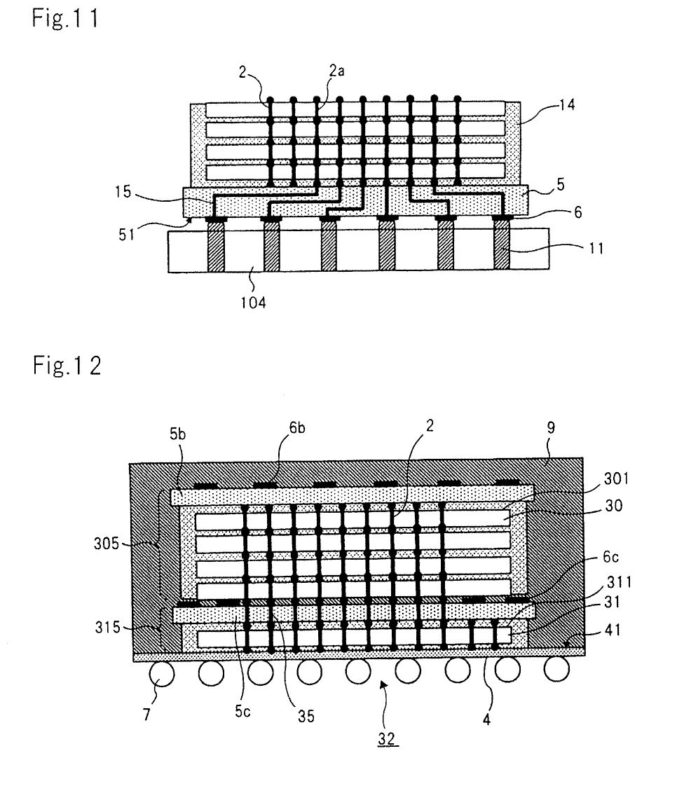

Next, a method of testing semiconductor chip 3 using chip stacked body 13 prior to mounting chip stacked body 13 on package substrate 4 will be described. FIG. 11 is a cross sectional view illustrative of a method of testing a semiconductor chip in a state of a chip stacked body.

A test for semiconductor chip 3 using substrate 5 is performed prior to mounting chip stacked body 13 on package substrate 4 as explained with reference to FIG. 10C. The through electrodes belonging to through electrode group 111 shown in FIG. 9 are used for transmission lines to transmit test signals for semiconductor chip 3.

An inspection apparatus, not shown, is connected to probe needles 11 of probe card 104 shown in FIG. 11 via a cable. A pitch between probe needles 11 is equal to a pitch between electrodes 6. The inspection apparatus (not shown) is provided with circuits to generate power supply voltage VDD and ground potential VSS and test signals including a chip select signal, address signal ADD, command signal CMD, and data DQ to be supplied to chip stacked body 13.

As shown in FIG. 11, substrate 5 provided with chip stacked body 13 is placed on probe card 104. In doing so, the positions of electrodes 6 provided on front surface 51 of substrate 5 and the positions of probe needles 11 are matched with each other, and electrodes 6 and probe needles 11 come into contact with each other. Subsequently, power supply voltage VDD and ground potential VSS are supplied to each of semiconductor chips 3 from the inspection apparatus (not shown) via probe needles 11, electrodes 6 of substrate 5, and through electrode group 113 shown in FIG. 9. The test signals are transmitted from the inspection apparatus to semiconductor chips 3 via probe needles 11 and through electrode group 111 shown in FIG. 9. Semiconductor chip 3 specified by the chip select signal receives the test signals supplied from the inspection apparatus via probe needles 11 to test circuit 24 shown in FIG. 9, and sends the results to the inspection apparatus via through electrode group 111, electrodes 6 of substrate 5, and probe needles 11.

Thus, power is supplied to semiconductor chips 3 via electrodes 6 and through electrode group 113 of substrate 5, and the test signals are transmitted to semiconductor chip 3 via electrodes 6 and through electrode group 111, so that the results of the test for semiconductor chip 3 are outputted via through electrode group 111 and electrodes 6. Therefore, it is possible to inspect the operation of semiconductor chip 3 prior to mounting chip stacked body 13 on package substrate 4.

Since electrodes 6 are arranged at a pitch larger than the pitch between through electrodes 2, the pitch between probe needles 11 of probe card 104 can also be made larger than the pitch between through electrodes 2. The pitch between probe needles 11 is made larger, so that it is possible to readily and reliably provide the insulating properties of probe needles 11.

It is noted that substrate 5 may be designed so as to match the pitch between electrodes 6 with the pitch between probe needles 11 of existing probe card 104 for preparing substrate 5. In this case, probe card 104 that has already been used can be used for testing chip stacked body 13 before chip stacked body 13 is used for packaging.

A test is performed in the state of chip stacked body 13, so that it is possible to determine whether through electrodes are firmly connected between adjacent semiconductor chips 3 in fabricating chip stacked body 13. Chip stacked body 13 in which a faulty connection has been found based on this test is not used for later packaging, so that it is possible to suppress the occurrence of faulty semiconductor device 1.

A test is performed on the state of chip stacked body 13 which makes it possible to test operation of the plurality of semiconductor chips 3 as a single device. If a defective chip within chip stacked body 13 can be found in this state, subsequent manufacturing steps will not be wastefully performed because chip stacked body 13 will be identified as faulty and will not be used.

As described above, it is possible to determine whether or not semiconductor chips 3 are defect free units and to determine whether there is a faulty connection between through electrodes prior to chip stacked body 13 being used for packaging. Semiconductor chips 3 and chip stacked body 13 that are determined to be defect free units, based on the test, are packaged on package substrate 4 with substrate 5 mounted thereon, and then semiconductor device 1 shown in FIG. 1 is fabricated.

In the semiconductor device according to this embodiment, a second substrate having second electrodes that are electrically connected to through electrodes of chips is provided on a chip stacked body having a plurality of chips stacked. Thus, even if stress occurs during expansion or contraction of through electrodes due to a temperature change or the like in the fabrication process, the stress will be released to the second substrate, so that it is possible to reduce stress applied to the chip and to prevent the chip from cracking.

A plurality of second electrodes are arranged at a second pitch larger than a pitch between the through electrodes, and the plurality of second electrodes are each electrically connected to a part of through electrodes among a plurality of through electrodes, so that it is possible to input/output signals between the chip and the outside via the second electrodes. Thus, power and test signals are supplied to the chips via the second electrodes prior to mounting the chip stacked body on the package substrate, so that it is possible to test the chip while it is in the state of being stacked in a single, chip stacked body.

### Second Embodiment

In the first embodiment, a plurality of semiconductor chips in the same type are mounted on the front surface side of the package substrate. This embodiment is configured such that different types of memory chips are mounted on the front surface side of a package substrate.

FIG. 12 is a cross sectional view illustrating an exemplary configuration of a semiconductor device according to this embodiment. The same configurations as those of the first embodiment are designated the same reference numerals and signs, and a detailed description is omitted.

As shown in FIG. 12, semiconductor device 32 according to this embodiment has different types of memory chips 30 and 31. Memory chips 30 and 31 are mounted on the front surface 41 side of package substrate 4. In the exemplary configuration shown in FIG. 12, four memory chips 30 are stacked, and substrate 5b is provided on the front surface 301 side of uppermost memory chip 30. Memory chip 31 is provided on package substrate 4, and substrate 5c is provided on the front surface 311 side of memory chip 31. In the following, structure 305 refers to a configuration in which substrate 5b is provided on a chip stacked body formed of four memory chips 30, and structure 315 refers to a configuration in which substrate 5c is provided on memory chip 31.

Substrate 5b is provided with electrodes 6b arranged at a pitch larger than the pitch between through electrodes 2. Substrate 5c is provided with electrodes 6c arranged at a pitch larger than the pitch between through electrodes 2, and is also provided with through electrodes 35 that connect chips 30 to chip 31. Thus, electrode 6c is disposed in the region where through electrode 35 has not been formed.

Memory chips 30 and 31 are semiconductor memory chips such as DRAM, SRAM, PRAM, and flash memory, for example. It is noted that the number of memory chips 30 is not limited to four.

Since a method of fabricating semiconductor device 32 according to this embodiment is similar to that of the first embodiment except that the process steps and the test, explained with reference to FIGS. 10A to 10C, are performed corresponding to memory chips 30 and 31, a detailed description is omitted.

In this embodiment, structure 305 and structure 315 are subjected to the test that has been performed on chip stacked body 13 of the first embodiment prior to mounting structure 305 and structure 315 on package substrate 4. In detail, power and test signals are supplied to memory chips 30 via electrodes 6b provided on substrate 5b of structure 305 for testing memory chip 30. Power and test signals are supplied to memory chip 31 via electrodes 6c provided on substrate 5c of structure 315 for testing memory chip 31.

After mounting structure 315 and structure 305 on package substrate 4 and packaging these structures with encapsulation resin 9, power and signals can be externally supplied to memory chip 31 via electrodes 7, and power and signals can be externally supplied to memory chips 30 via electrodes 7, through electrodes of memory chip 31, and through electrodes 35 of substrate 5c.

In the semiconductor device according to this embodiment, substrate 5b is provided on the front surface side of memory chip 30, and substrate 5c is provided on the front surface side of memory chip 31. Thus, it is possible to prevent memory chips 30 and 31 from cracking during the fabrication process as well as to test memory chips prior to packaging memory chips. Chips 30 and chip 31 that are determined to be defect free units in the test are mounted on package substrate 4, so that it is possible to prevent the occurrence of faults in semiconductor device 32.

It is apparent that the present invention is not limited to the above embodiments, but may be modified and changed without departing from the scope and spirit of the invention.

What is claimed is:

1. A device comprising:
a first substrate including a plurality of first electrodes;
a plurality of chips each including a plurality of through electrodes, the chips being stacked with each other such that the through electrodes of a lower one of the chips are connected respectively the through electrodes of an upper one of the chips to provide a chip stacked body; and
a second substrate cooperating the first substrate to sandwich the chip stacked body between the first and second substrates, the second substrate including a plurality of second electrodes on a first surface that is opposite to a second surface facing the chip stacked body, each of the second electrodes being electrically connected to an associated one of the through electrodes of an uppermost one of the chips of the chip stacked body.

2. The device according to claim 1, wherein the second substrate is formed in a semiconductor substrate as a wiring board, and each of the chips being a semiconductor memory chip.

3. The device according to claim 1, wherein the second substrate is formed in an insulating substrate as a wiring board, and each of the chips being a semiconductor memory chip.

4. The device according to claim 1, wherein the through electrodes are arranged at a first pitch, the first electrodes being arranged at a second pitch larger than the first pitch, and the second electrodes being arranged at a third pitch larger than the first pitch.

5. The device according to claim 1, further comprising an insulating film covering the second substrate and the chips to render the second electrodes unexposed, wherein the first electrodes of the first substrate are exposed on an outside of the device.

6. The device according to claim 1, further comprising a controller chip provided between the first substrate and the chip stacked body.

7. The device according to claim 6, wherein the controller chip includes a control circuit, the control circuit receiving a plurality of external signals from an outside of the device through the first electrodes and generating a plurality of internal signals in response to the external signals to selected ones of the through electrodes.

8. A semiconductor device comprising:
a first wiring board including a plurality of first electrodes;
a first chip provided on the first wiring board and including a plurality of first through electrodes;
a second chip provided on the first chip such that the first chip is sandwiched between the first wiring board and the second chip and including a plurality of second through electrodes connected to the first through electrodes, respectively;
a second wiring board provided on the second chip such that the second chip is sandwiched between the first chip and the second wiring board, the second wiring board including a plurality of second electrodes on a first surface facing the second chip and a plurality of third electrodes on a second surface opposing to the first surface, the second electrodes being connected to the second through electrodes of the second chip, respectively, and the third electrodes being electrically connected to selected ones of the second electrodes, respectively.

9. The semiconductor device according to claim 8, wherein, the first and second through electrodes are arranged at a first pitch, the first electrodes being arranged at a second pitch larger than the first pitch, and the third electrodes being arranged at a third pitch larger than the first pitch.

10. The semiconductor device according to claim 9, wherein the second electrodes are arranged at the first pitch.

11. The semiconductor device according to claim 8,
wherein the first wiring board further includes a third surface facing the first chip and a fourth surface opposing to the third surface, the first electrodes being provided on the fourth surface.

12. The semiconductor device according to claim 8,
wherein the first and second chips further include first and second test circuits, respectively, the second test circuit of the second chip being electrically connected to selected ones of the second through electrodes that are connected to the selected ones of the second electrodes, respectively, and the first test circuit of the first chip being electrically connected to selected ones of the first through electrodes that are connected to the selected ones of the second through electrodes, respectively.

13. The semiconductor device according to claim 8, further comprising a controller chip provided between the first wiring board and the first chip.

14. The semiconductor device according to claim 13,
wherein the controller chip includes a control circuit receiving a plurality of external signals from an outside of the semiconductor device through the first electrodes to generate a plurality of internal signals in response to the external signals to selected ones of the first and second through electrodes.

15. The semiconductor device according to claim 8,
wherein the second wiring board further includes a plurality of interconnections connecting the selected ones of the second electrodes to the third electrodes, respectively.

16. The semiconductor device according to claim 8,
wherein each of the third electrodes is larger than the second electrodes.

17. The semiconductor device according to claim 8, further comprising an insulating film covering the first and second chips, the second wiring board and the third electrodes of the second wiring board,
wherein the first electrodes of the first wiring board are exposed from the insulating film.
